(19) United States
(12) Patent Application Publication
(10) Pub. No.: US 2005/0240856 A1
(43) Pub. Date: Oct. 27, 2005

(54) Hologram recording and reproducing apparatus and hologram reproducing apparatus

(75) Inventor: Hideki Hayashi, Yokohama (JP)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/094,690

(22) Filed: Mar. 31, 2005

(30) Foreign Application Priority Data
Apr. 6, 2004 (JP) 2004-112363
Oct. 9, 2004 (KR) 2004-80734

(51) Int. Cl. H03M 13/00; G06F 11/00

(52) U.S. Cl. 714/800

(57) ABSTRACT

A hologram recording and reproducing apparatus having a reduced encoding error and high reliability even when a signal-to-noise (S/N) ratio of reproducing signals is deteriorated due to various disturbances. The hologram recording and reproducing apparatus includes: a unit generating a recording low-density parity check code from recording data; a unit generating a recording block code from the recording low-density parity check code; a unit recording data by emitting an object beam onto a hologram recording medium; a unit reproducing data by emitting a reference beam onto the hologram recording medium; a unit decoding a reproducing block code corresponding to the recording block code based on the levels of a reproducing signal, decoding a reproducing low-density parity check code corresponding to the recording low-density parity check code based on the reproducing block code, and calculating estimation data estimating values of respective bits of the reproducing low-density parity check code based on the level of the level of the reproducing signals; and a unit decoding the low-density parity check code based on the estimation data and decoding the recording data.

### CROSS-REFERENCE TO RELATED APPLICATIONS

This application claims the benefit of Japanese Patent Application No. 2004-112363, filed Apr. 6, 2004 in the Japanese Intellectual Property Office, the priority of Korean Patent Application No. 2004-80734, filed Oct. 9, 2004 in the Korean Intellectual Property Office, the disclosures of which are incorporated herein in their entirety by reference.

### BACKGROUND OF THE INVENTION

1. Field of the Invention

The present invention relates to a hologram recording and reproducing apparatus and a hologram reproducing apparatus to record data to a hologram medium and to reproduce the recorded data, and, more particularly, to a hologram recording and reproducing apparatus and a hologram reproducing apparatus which reduce a decoding error even when a signal-to-noise (S/N) ratio of a reproduced signal deteriorates due to disturbances.

2. Description of the Related Art

Recently, rewritable optical disks such as phase-change optical disks and magneto-optical disks have become wide spread. With such optical disks, a technology in which a beam-spot diameter is reduced is required to enhance recording density. Such technology allows a distance between adjacent tracks or between adjacent bits to be reduced so as to enhance recording density.

The density of such optical disks has increased year by year. However, a recording density of data in the plane of the optical disk is restricted by a diffractive limit of light. Therefore, three-dimensional multiple recording in which a depth of the optical disk is used is required to increase storage capacity.

Therefore, as next-generation computer memory, hologram memory having a large capacity due to a three-dimensional recording area and high speed due to a two-dimensional batch recording and reproducing method is being developed. In the hologram memory, an object beam and a reference beam corresponding to recording data are made incident on a recording medium in which a recording layer made of, for example, photopolymer, etc., is interposed between two glass plates. An interference pattern is then generated by the beams causing variations in the refractive index of the recording material so as to record data. Further, by emitting only the reference beam onto the recording material in a data reproducing operation, optical data corresponding to the recording data is extracted by a reproduction of the interference pattern.

A signal processor of such a conventional hologram recording and reproducing apparatus is illustrated in FIG. 1. Referring to FIG. 1, a Reed-Solomon encoder 1 encodes recording data a using a Reed-Solomon code and generates a recording Reed-Solomon code b. A block encoder 2 encodes the recording Reed-Solomon code b, by using a block code, and generates a recording block code d. For example, referring to FIG. 2, if b=0, d is given by equation 1. Conversely, if b=1, an encoding process uses a differential code in which d is given by equation 2 is performed.

$$\begin{matrix}d = [ \begin{matrix}0 \\ 1\end{matrix} ] & ( 1 ) \\ d = [ \begin{matrix}1 \\ 0\end{matrix} ] & ( 2 )\end{matrix}$$

Referring to FIG. 1, a space modulator 3 generates recording-page data indicating a checkered pattern corresponding to the recording block code d by transmitting the object beams of pixels corresponding to “1” in the recording block code d and intercepting the object beams of pixels corresponding to “0”. For example, when d is given by equation 3, the recording-page data shown in FIG. 3 is generated. In another method, a code, (hereinafter, referred to as a 2:4 code) in which one of four pixels is “1” and the other three pixels are “0,” is used (for example, see Japanese Patent Application Laid-open No. H9-197947).

$$d = [ \begin{matrix}0 & 1 & 0 & 1 & 1 & 0 \\ 1 & 0 & 1 & 0 & 0 & 1\end{matrix} ] \qquad ( 3 )$$

The brightness levels of the pixels in the first row of the recording-page data shown in FIG. 3 is illustrated in FIG. 4 . Each of the pixels of the recording-page data is either white or black, i.e., each of the respective pixels represents a discrete binary level.

Referring again to FIG. 1, a hologram recording medium 4 is formed by depositing a photosensitive material on a disk substrate, and the recording-page data is recorded thereon when the interference pattern of the reference beam and the object beam causes a variation in the refractive index of the photosensitive material. By emitting the reference beam onto the hologram recording medium, reproducing-page data having a checkered pattern corresponding to the recording-page data may be obtained. The reproducing-page data obtained by recording the recording-page data shown in FIG. 3 on the hologram recording medium 4 and then reproducing the reproducing-page data from the hologram recording medium 4 are shown in FIG. 5. The brightness levels of the pixels represented by the first row of the reproducing-page data shown in FIG. 5 are shown in FIG. 6.

In this way, the respective levels of each pixel of the reproducing-page data are gray between white and black, and the brightness levels of the respective pixels have a continuous multi-valued level. This is due to the fact that the levels of the reproducing signals are changed due to various disturbances, such as media noise, system noise, interference between codes, cross-talk, deviation in pixel position, etc., in the hologram recording and reproducing apparatus.

A light receiver 5 having a CMOS image sensor or a CCD image sensor photo-electrically converts the reproducing-page data so as to obtain a reproducing signal p. The reproducing signal p has a continuous multi-valued level, which is similar to the brightness levels shown in FIG. 6. A block decoder 6 decodes the block code based on the level of the reproducing signal p and generates a reproducing Reed-Solomon code r.

That is, assuming that the values of the reproducing signal reproduced from adjacent up and down pixels on the light receiver 5 are P₁ and P₂, the block decoder 6 determines that the estimated value of the recording block code d is given by equation 4 if p₁<p₂ and generates a reproducing Reed-Solomon code of r=0. On the other hand, if p₁>p₂, the block decoder 6 determines that the estimated value of d is given by equation 5 and generates a reproducing Reed-Solomon code of r=1. The Reed-Solomon decoder 7 decodes the reproducing Reed-Solomon code r using a Reed-Solomon code and generates reproducing data s.

$$\begin{matrix}\hat{d} = [ \begin{matrix}0 \\ 1\end{matrix} ] & ( 4 ) \\ \hat{d} = [ \begin{matrix}1 \\ 0\end{matrix} ] & ( 5 )\end{matrix}$$

In the above-described conventional hologram recording and reproducing apparatus, the reproducing data s must be equal to the recording data a with relatively high reliability, and the bit error rate of the reproducing Reed-Solomon code r must be reduced to less than, for example, 1×10⁻⁴, before performing the decoding process with the Reed-Solomon code. However, in an actual hologram recording and reproducing apparatus, the signal-to-noise (S/N) ratio of the reproducing signals may deteriorate relatively easily due to various disturbances such as media noise, system noise, interference between codes, cross-talk, deviation in pixel position, etc. For this reason, a decoding error of the reproducing Reed-Solomon code r often happens and the bit error rate often deteriorates to, for example, 1×10⁻².

As is described above, each pixel of the reproducing-page data is gray between white and black, and the brightness levels of the respective pixels and the levels of the reproducing signals are continuous multi-valued levels. Since the block code is decoded based only on the relative level of the reproducing signal p having a multi-valued level, the decoding error is often generated when the disturbance of the level of the reproducing signal p causes large variations in the reproducing signal p.

### SUMMARY OF THE INVENTION

The present invention provides a hologram recording and reproducing apparatus and a hologram reproducing apparatus each of which provides a reduced decoding error and high reliability even when a signal-to-noise (S/N) ratio of reproducing signals is deteriorated due to various disturbances by performing a high-performance decoding process using a low-density parity check (LDPC) code.

According to an aspect of the present invention, there is provided a hologram recording and reproducing apparatus comprising: a low-density parity check encoding unit to encode recording data using a low-density parity check code and to generate a recording low-density parity check code; a block encoding unit to encode the recording low-density parity check code using a block code and to generate a recording block code; a hologram recording unit to record the data by emitting an object beam with a brightness modulated by a space modulator according to the recording block code onto a hologram recording medium; a hologram reproducing unit including a light-receiver to reproduce the data by photo-electrically transforming a reproducing beam obtained by emitting a reference beam onto the hologram recording medium into a reproducing signal; a block decoding unit to decode a reproducing block code corresponding to the recording block code based on the level of the reproducing signal, to decode a reproducing low-density parity check code corresponding to the recording low-density parity check code based on the reproducing block code, and to calculate estimation data to estimate values of respective bits of the reproducing low-density parity check code based on the level of the reproducing signal; and a low-density parity check decoding unit to decode the low-density parity check code based on the estimation data and to decode the recording data.

According to the embodiment described above, the recording low-density parity check code corresponding to the recording data is generated by the low-density parity check encoding unit. The recording block code corresponding to the recording low-density parity check code is generated by the block encoding unit, and the data recording is performed by emitting an object beam with brightness modulated by a space modulator in accordance with the recording block code onto the hologram recording medium. On the other hand, for the data reproduced by the light-receiver by photo-electrically transforming a reproducing beam obtained by emitting a reference beam onto the hologram recording medium into reproducing signals, the block decoding unit decodes the reproducing block code corresponding to the recording block code based on the level of the reproducing signals, decodes the reproducing low-density parity check code corresponding to the recording low-density parity check code based on the reproducing block code, and calculates the estimation data estimating values of respective bits of the reproducing low-density parity check code based on the level of the reproducing signals. The reproducing low-density parity check code is decoded based on the estimation data by the low-density parity check decoding unit so as to decode the recording data.

According to another aspect of the present invention, there is provided a A hologram reproducing apparatus to reproduce data recorded in a hologram recording medium by a hologram recorder including a low-density parity check encoding unit to encode recording data using a low-density parity check code and to generate a recording low-density parity check code, a block encoding unit to encode the recording low-density parity check code using a block code and to generate a recording block code, and a hologram recording unit to record the data by emitting an object beam with a brightness modulated by a space modulator according to the recording block code onto the hologram recording medium, the apparatus comprising a hologram reproducing unit including a light-receiver to reproduce the data by photo-electrically transforming a reproducing beam obtained by emitting a reference beam onto the hologram recording medium into a reproducing signal, a block decoding unit to decode a reproducing block code corresponding to the recording block code based on the level of the reproducing signal, to decode a reproducing low-density parity check code corresponding to the recording low-density parity check code based on the reproducing block code, and to calculate estimation data to estimate values of respective bits of the reproducing low-density parity check code based on the level of the reproducing signal, and a low-density parity check decoding unit to decode the low-density parity check code based on the estimation data and to decode the recording data.

According to the embodiment described above, the data reproducing is performed by the light-receiver by photo-electrically transforming a reproducing beam obtained by emitting a reference beam onto the hologram recording medium into reproducing signals. As for the data, the block decoding unit decodes the reproducing block code corresponding to the recording block code based on the level of the reproducing signals, decodes the reproducing low-density parity check code corresponding to the recording low-density parity check code based on the reproducing block code, and calculates the estimation data estimating values of respective bits of the reproducing low-density parity check code are calculated based on the level of the reproducing signals. The reproducing low-density parity check code is decoded on the basis of the estimation data by the low-density parity check decoding unit so as to decode the recording data.

In both the hologram recording and reproducing apparatus and the hologram reproducing apparatus, the absolute value of the estimation data may be proportional to a difference in levels of the reproducing signal obtained from respective pixels of the light receiver, and the polarity of the estimation data may correspond to the polarity of each of the bits of the reproducing low-density parity check code.

According to the present invention described above, since the absolute value of the estimation data of the LDPC code is proportional to the difference in levels of the reproducing signal obtained from the respective pixels of the light receiver, the error correction ability of the LDPC code may be enhanced, so that a reduction of the bit error rate of the reproducing Reed-Solomon code is possible.

In both the hologram recording and reproducing apparatus and the hologram reproducing apparatus, the block encoding unit generates the recoding block code such that M of N pixels in the space modulator indicate “1” and (N-M) of the N pixels indicate “0” (where N and M are natural numbers, N>M), the block decoding unit may select M of the N pixels of the light receiver in order of increasing level of the reproducing signal and decode the reproducing block code by setting the selected M pixels to “1” and the (N-M) pixels to “0”, and the block decoding unit may add the levels of the reproducing signal of the pixels set to “1”, subtract the levels of the reproducing signal of the pixels set to “0”, and calculate the estimation data proportional to the added and subtracted levels.

According to the present invention described above, since the high-performance signal processing with the LDPC code is performed using the estimation data calculated from the difference in levels of the reproducing signal, a reduction of the bit error rate of the reproducing Reed-Solomon code is possible compared to a case where the data are determined by considering only the relative size of the reproducing signal.

In the hologram recording and reproducing apparatus and the hologram reproducing apparatus, when the reproducing block code does not exist in a code word of a block code, the estimation data of the respective bits of the reproducing low-density parity check code decoded based on of the reproducing block code may be set to 0.

According to the present invention described above, when the reproducing block code does not correspond to a code word of the LDPC code, the estimation data of the reproducing block code is not used for the encoding process of the LDPC code, so that prevention of deterioration of the decoding performance due to erroneous estimation data is possible.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a conventional signal processor of a hologram recording and reproducing apparatus;

FIG. 2 is a diagram illustrating exemplary brightness levels of respective pixels;

FIG. 3 is a diagram illustrating exemplary recording-page data;

FIG. 4 is a diagram illustrating exemplary levels of the recording-page data of FIG. 3;

FIG. 5 is a diagram illustrating exemplary reproducing-page data; and

FIG. 6 is a diagram illustrating exemplary levels of the reproducing-page data of FIG. 5.

FIG. 7 is a block diagram of a signal processor of a hologram recording and reproducing apparatus according to an embodiment of the present invention;

FIG. 8 is a circuit diagram of a low-density parity check (LDPC) encoder according to an embodiment of the present invention;

FIG. 9 is a diagram illustrating exemplary brightness levels of respective pixels produced according to an embodiment of the present invention;

FIG. 10 is a diagram illustrating exemplary recording-page data produced according to an embodiment of the present invention;

FIG. 11 is a diagram illustrating exemplary brightness levels of respective pixels produced according to an embodiment of the present invention;

FIG. 12 is diagram illustrating exemplary recording-page data produced according to an embodiment of the present invention;

FIG. 13 is a diagram exemplifying a relation ship between recording-page data and reproducing-page data according to another embodiment of the present invention.

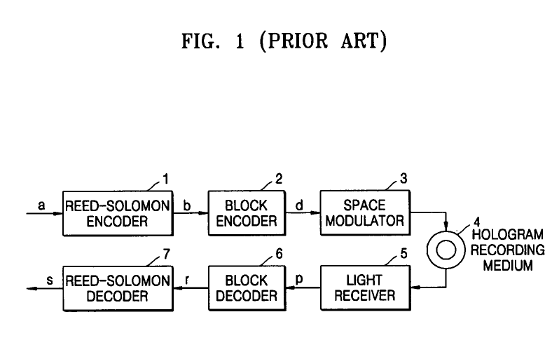

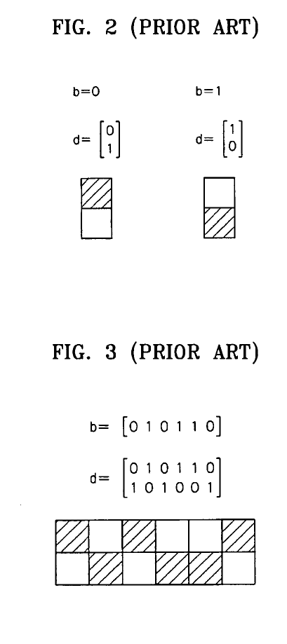

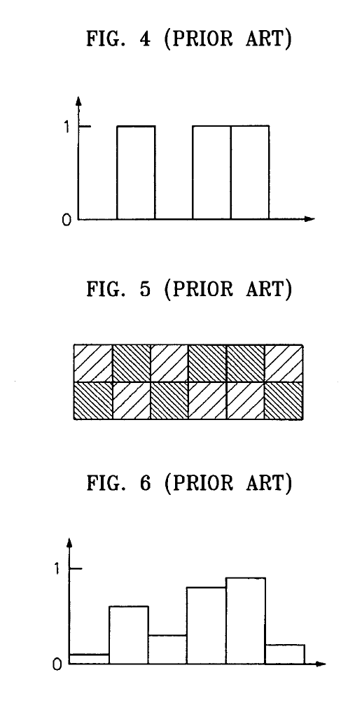

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

### FIRST EMBODIMENT

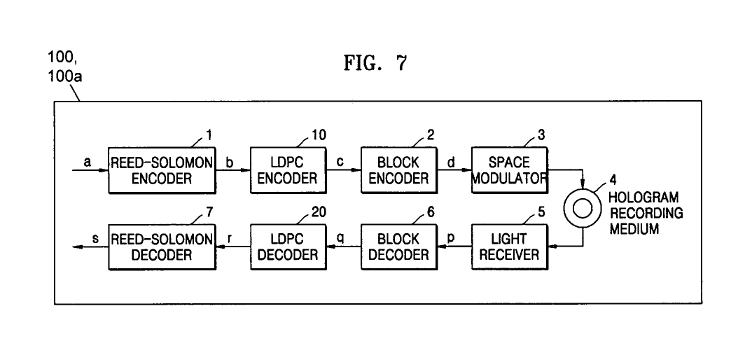

Referring to FIG. 7, a signal processor of a hologram recording and reproducing apparatus 100 and a hologram reproducing apparatus 100a according to a first embodiment of the present invention includes, a Reed-Solomon encoder 1, a low-density parity check (LDPC) encoder 10, a block encoder 2, a space modulator 3, a light receiver 5, a block decoder 6, an LDPC decoder 20, and a Reed-Solomon decoder 7.

The Reed-Solomon encoder 1 encodes recording data a using a Reed-Solomon code and generates a recording Reed-Solomon code b. The LDPC encoder 10 encodes the recording Reed-Solomon code b using an LDPC code and generates a recording LDPC code c.

The block encoder 2 encodes the recording LDPC code c using a block code and generates a recording block code d. The space modulator 3 transmits or intercepts object beams of respective pixels, and generates recording-page data having a checkered pattern corresponding to the recording block code d. A hologram recording medium 4 is formed, for example, by depositing a photosensitive material on a disk substrate. Data is recorded on the hologram recording medium 4 when a reference beam and an object beam forms an interference pattern corresponding to the recording-page data by creating variations in the refractive index of the photosensitive material. By emitting the reference beam onto the hologram recording medium, reproducing-page data may be obtained in the form of a checkered pattern corresponding to the recording-page data.

The light receiver 5 having a CMOS image sensor or a CCD image sensor photo-electrically converts the reproducing-page data into a reproducing signal p. The block decoder 6 decodes a reproducing block code corresponding to the recording block code d based on the levels of the reproducing signal p, decodes a reproducing LDPC code corresponding to the recording LDPC code c based on the reproducing block code, and calculates estimation data q. The estimation data q indicates the accuracy of respective bits of the reproducing LDPC code based on the levels of the reproducing signal p.

The LDPC decoder 20 decodes the LDPC code based on the estimation data q and generates a reproducing Reed-Solomon code r. The Reed-Solomon decoder 7 decodes the reproducing Reed-Solomon code r using a Reed-Solomon code and generates reproducing data s.

Operations of the LDPC encoder 10, the LDPC decoder 20, and the block decoder 6 shown in FIG. 7 will now be described in detail.

The LDPC encoder 10 generates an LDPC code by multiplying input data by a generating matrix (G). The LDPC code is completely defined by a parity check matrix H. A case in which the parity check matrix H is given by equation 6 will be now described. The generating matrix G is given by equation 7. Therefore, when the recording Reed-Solomon code b is given by equation 8, the recording LDPC code c is given by equation 9. By encoding the recording LDPC code c using a differential code, the recording block code d given by equation 3 may be obtained, and the recording-page data illustrated in FIG. 3 may be obtained.

$$\begin{matrix}H = [ \begin{matrix}1 & 1 & 0 & 1 & 0 & 0 \\ 0 & 1 & 1 & 0 & 1 & 0 \\ 1 & 0 & 1 & 0 & 0 & 1\end{matrix} ] & ( 6 ) \\ G = [ \begin{matrix}1 & 0 & 0 & 1 & 0 & 1 \\ 0 & 1 & 0 & 1 & 1 & 0 \\ 0 & 0 & 1 & 0 & 1 & 1\end{matrix} ] & ( 7 ) \\ b = [ \begin{matrix}0 & 1 & 0\end{matrix} ] & ( 8 ) \\ c = b G = [ \begin{matrix}0 & 1 & 0\end{matrix} ] [ \begin{matrix}1 & 0 & 0 & 1 & 0 & 1 \\ 0 & 1 & 0 & 1 & 1 & 0 \\ 0 & 0 & 1 & 0 & 1 & 1\end{matrix} ] = [ \begin{matrix}0 & 1 & 0 & 1 & 1 & 0\end{matrix} ] & ( 9 )\end{matrix}$$

The LDPC decoder 20 decodes the LDPC code using a sum-product decoding method to be described later. Assuming, for example, that the number of rows in the parity check matrix H is M and the number of columns is N, then M=3 and N=6 is obtained in equation 6.
[Operation 1: Initialization]

First, for all pairs (m, n) such that the (m, n) component of the parity check matrix is 1, that is, Hₘₙ=1, let a logarithmic pre-value ratio, βₘₙ=0.
[Operation 2: Row Processing]

Next, for all pairs (m, n) such that Hₘₙ=1 in the respective rows for m=1, 2, . . . , M, a logarithmic exterior-value ratio, αₘₙ is calculated from equation 10.

In equation 10, the sign function indicates polarity, and is defined by equation 11.

$$\begin{matrix}{α}_{mn} = ( {\prod }_{{n}^{′} ∈ A ( m ) \backslash n} sign ( {q}_{{n}^{′}} + {β}_{{mn}^{′}} ) ) f ( {\sum }_{{n}^{′} ∈ A ( m ) \backslash n} f ( \vert {q}_{{n}^{′}} + {β}_{{mn}^{′}} \vert ) ) & ( 10 ) \\ sign ( x ) = \{ \begin{matrix}1 , & x \geq 0 \\ - 1 , & x < 0\end{matrix} & ( 11 )\end{matrix}$$

f(x) is a Gallager function and is defined by equation 12.

Estimation data qₙ are given by a logarithmic ratio of conditional probability that the level of the reproducing signal is p when the n-th column component cₙ of the recording LDPC code c is 0 or 1, and is given by equation 13. Equation 14, included in equation 10, means the operation that calculates the multiplication or summation of the m-th row components of all the columns other than the n-th column components.

$$\begin{matrix}f ( x ) = ln \frac{exp ( x ) + 1}{exp ( x ) - 1} & ( 12 ) \\ {q}_{n} = ln \frac{P ( p \vert {c}_{n} = 0 )}{P ( p \vert {c}_{n} = 1 )} & ( 13 ) \\ {n}^{′} ∈ A ( m ) \backslash n & ( 14 )\end{matrix}$$

[Operation 3: Column Processing]

For all pairs (m, n) such that Hₘₙ=1 in the respective columns of n=1, 2, . . . , N, a logarithmic pre-value ratio, βₘₙ=0 is calculated from equation 15. Equation 16, included in equation 15, sums the n-th column components of all the rows other than the m-th row using a variable m′ representing the location of the column. Operation 2 and operation 3 are repeated a predetermined number of times and then operation 4 is performed.

$$\begin{matrix}{β}_{mn} = {\sum }_{{m}^{′} ∈ B ( n ) \backslash m} {α}_{{m}^{′} n} & ( 15 ) \\ {m}^{′} ∈ B ( n ) \backslash m & ( 16 )\end{matrix}$$

[Operation 4: Decoding Code Word]

In this operation, for n=1, 2, . . . , N, the n-th column component rₙ of the reproducing code r is decoded using equation 17. Then the algorithm is terminated. Equation 18, included in equation 17, sums all n-th column components using a variable m′ representing the location of column.

$$\begin{matrix}{r}_{n} = \{ \begin{matrix}0 , & if sign ( {q}_{n} + {\sum }_{{m}^{′} ∈ B ( n )} {α}_{{m}^{′} n} ) = 1 \\ 1 , & if sign ( {q}_{n} + {\sum }_{{m}^{′} ∈ B ( n )} {α}_{{m}^{′} n} ) = - 1\end{matrix} & ( 17 ) \\ {m}^{′} ∈ B ( n ) & ( 18 )\end{matrix}$$

An example of the sum-product decoding method will now be described when the parity check matrix H is given by equation 6. Here, operation 2 is repeated twice and then operation 4 is performed.

[Operation 1]
β₁₁=β₁₂=β₁₄=0
β₂₂=β₂₃=β₂₅=0
β₃₁=β₃₃=β₃₆=0 (19)
[Operation 2 (First Time)]
α₁₁=(sign(q₂).sign(q₄))f(f(|q₂|)+f(|q₄|))
α₁₂=(sign(q₁).sign(q₄))f(f(|q₁|)+f(|q₄|))
α₁₄=(sign(q₁).sign(q₂))f(f(|q₁|)+f(|q₂|))
. . .
α₃₆=(sign(q₁).sign(q₃))f(f(|q₁|)+f(|q₃|)) (20)
[Operation 3]
β₁₁=α₃₁
β₃₁=α₁₁
β₁₂=α₂₂
. . .
β₃₆=0 (21)
[Operation 2 (Second Time)]
α₁₁=(sign(q₂+β₁₂).sign(q₄+β₁₄))f(f(|q₂+β₁₂|)+f(|q₄+β₁₄|))
α₁₂=(sign(q₁+β₁₁).sign(q₄+β₁₄))f(f(|q₁+β₁₁|)+f(|q₄+β₁₄|))
α₁₄=(sign(q₁+β₁₁).sign(q₂+βhd 12))f(f(|q₁+β₁₁|)+f(|q₂+β₁₂|))
. . .
α₃₆=(sign(q₁+β₃₁).sign(q₃+β₃₃))f(f(|q₁+β₃₁|)+f(|q₃+β₃₃|)) (22)
(Operation 4)

$${r}_{1} = \{ \begin{matrix}0 , & if sign ( {q}_{1} + {α}_{11} + {α}_{31} ) = 1 \\ 1 , & if sign ( {q}_{1} + {α}_{11} + {α}_{31} ) = - 1\end{matrix} \\ {r}_{2} = \{ \begin{matrix}0 , & if sign ( {q}_{2} + {α}_{12} + {α}_{22} ) = 1 \\ 1 , & if sign ( {q}_{2} + {α}_{12} + {α}_{22} ) = - 1\end{matrix} \\ {r}_{3} = \{ \begin{matrix}0 , & if sign ( {q}_{3} + {α}_{23} + {α}_{33} ) = 1 \\ 1 , & if sign ( {q}_{3} + {α}_{23} + {α}_{33} ) = - 1\end{matrix} \\ ⋯ \\ {r}_{6} = \{ \begin{matrix}0 , & if sign ( {q}_{6} + {α}_{36} ) = 1 \\ 1 , & if sign ( {q}_{6} + {α}_{36} ) = - 1\end{matrix} \qquad ( 23 )$$

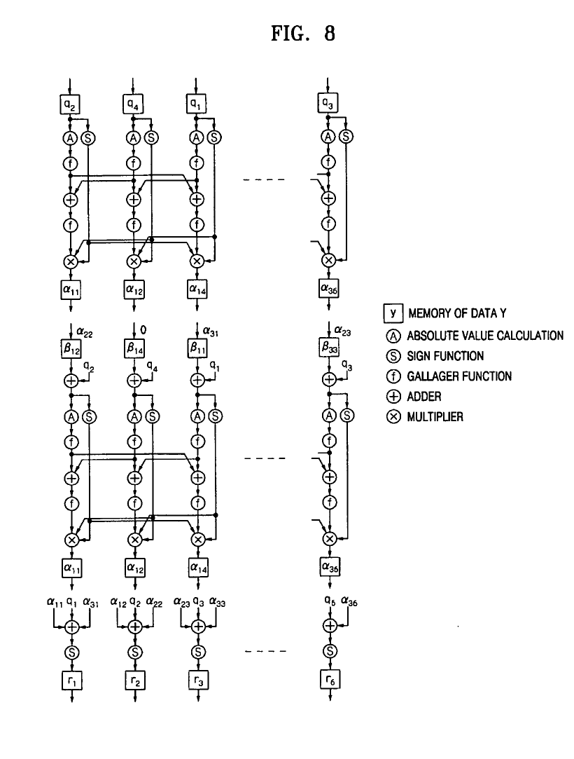

FIG. 8 is a circuit diagram of the LDPC decoder 20. This circuit structure has a pipeline shape in which data flows from the upside to the downside, and continuous signals are input thereto. However, the circuit structure is not limited to the pipeline shape and may have a circular shape in which calculation results are fed back to update the contents of the memory. The Gallager function may be embodied in a look-up table. In calculating absolute values, the most significant bit of a code may be set to a positive value. The sign function may extract the most significant bit of a code and the product between the sign functions may be simply embodied as an exclusive logical sum calculation.

As shown in FIGS. 7 and 8, the LDPC decoder 20 receives the estimation data q, performs the sum-product decoding method, and then outputs the reproducing Reed-Solomon code r. Therefore, the block decoder 6 according to the present embodiment calculates the level difference A between the levels of the reproducing signal p to obtain the estimation data q, and inputs the estimation data q to the LDPC decoder 20.

Assuming that the probability distribution of the reproducing signals p corresponds to a Gaussian distribution with an average m and a variance σ², then the probability density function of the reproducing signals p is given by equation 24. When the differential code is used as the block code, the estimation data q of equation 13 is given by equation 25.

$$\begin{matrix}P ( p ) = \frac{1}{\sqrt{2 {πσ}^{2}}} exp \{ - \frac{{( p - m )}^{2}}{2 {σ}^{2}} \} & ( 24 ) \\ \begin{matrix}q = ln \frac{P ( p \vert c = 0 )}{P ( p \vert c = 1 )} \\ = ln \frac{\frac{1}{\sqrt{2 {πσ}^{2}}} exp \{ - \frac{{( {p}_{2} - {p}_{1} - 1 )}^{2}}{2 {σ}^{2}} \}}{\frac{1}{\sqrt{2 {πσ}^{2}}} exp \{ - \frac{{( {p}_{2} - {p}_{1} + 1 )}^{2}}{2 {σ}^{2}} \}} \\ = \frac{2 ( {p}_{2} - {p}_{1} )}{{σ}^{2}}\end{matrix} & ( 25 )\end{matrix}$$

That is, assuming that the levels of the reproducing signal of adjacent up and down pixels of the light receiver 5 are p₁ and P₂, the level difference Δ is obtained from equation 26, and is multiplied by a constant of proportionality, thus the estimation data q may be calculated as shown by equation 27. Here, the variance (σ²) may be actually measured from the reproducing signal p using a calculation circuit, or a predetermined value stored in a memory may be used.

$$\begin{matrix}Δ = {p}_{2} - {p}_{1} & ( 26 ) \\ q = \frac{2 Δ}{{σ}^{2}} & ( 27 )\end{matrix}$$

As is described above, in the present embodiment, by combining the block code and the LDPC code, the reproducing data equal to the recording data may be reproduced with high reliability. In the reproducing-page data reproduced from the hologram recording medium, the brightness levels of the respective pixels are varied due to various disturbances and thus have multi-valued gray levels. However, in the present embodiment, since the estimation data of the LDPC code is calculated effectively using level data of the reproducing signals having a multi-valued level, the error correcting ability of the LDPC code may be enhanced so as to reduce the bit error rate of the reproducing Reed-Solomon code.

### SECOND EMBODIMENT

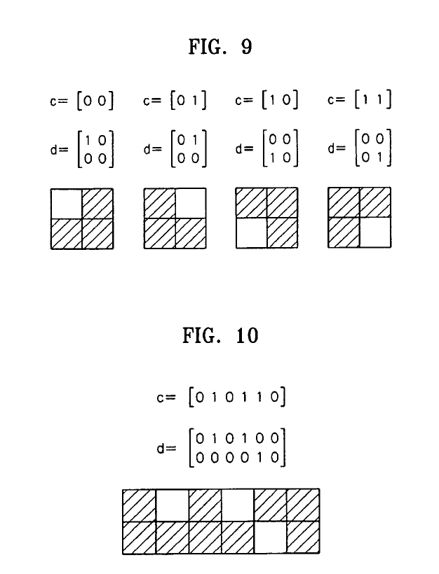

Although a differential code is used as the block code in the first embodiment, a 2:4 code may also be used. An encoding rule of the 2:4 code is illustrated in FIG. 9 and an example of the recording-page data is illustrated in FIG. 10.

In this case, the block decoder 6 compares the brightness levels of four pixels constituting code words of the 2:4 code and sets levels of the pixels to P₁, P₂, P₃, and p₄ in order of increasing brightness. The level difference Δ may be given by, for example, equation 28, equation 29 or equation 30.

$$\begin{matrix}Δ = {p}_{1} - ( {p}_{2} + {p}_{3} + {p}_{4} ) & ( 28 ) \\ Δ = {p}_{1} - \frac{{p}_{1} + {p}_{2} + {p}_{3} + {p}_{4}}{4} & ( 29 ) \\ Δ = {p}_{1} - {p}_{2} & ( 30 )\end{matrix}$$

Referring to FIG. 9, when the brightness level of the right-upper pixel is highest, the reproducing block code \hat{d}, which is an estimated value of the recording block code d, is given by equation 31 and the reproducing LDPC code ĉ, which is an estimated value of the recording LDPC code c, is given by equation 32.

$$\begin{matrix}\hat{d} = [ \begin{matrix}0 & 1 \\ 0 & 0\end{matrix} ] & ( 31 ) \\ \hat{c} = [ \begin{matrix}0 & 1\end{matrix} ] & ( 32 )\end{matrix}$$

Since the estimated reproducing LDPC code is proportional to the level difference Δ, the estimation data q₁ of the first column and the estimation data q₂ of the second column of the estimated reproducing LDPC code are given by equation 33s. When the estimated recording LDPC code cₙ=0 is greater than equation 13, qn is positive, and when the likelyhood of cₙ=1 is greater than equation 13, qₙ is negative. Therefore, q₁ is positive and q₂ is negative in equation 33.

$${q}_{1} = \frac{2 Δ}{{σ}^{2}} \\ {q}_{2} = - \frac{2 Δ}{{σ}^{2}} \qquad ( 33 )$$

As is described above, the block decoder 6 according to the present embodiment: (1) selects a predetermined number of pixels from the pixels constituting the code word in order of increasing brightness, (2) decodes a reproducing block code by setting the selected pixels to “1” and setting the other pixels to “0”, (3) decodes a reproducing LDPC code based on the reproducing block code, (4) calculates a level difference Δ by adding the brightness levels of the pixels set to “1” and subtracting the brightness levels of the pixels set to “0”, and (5) generates estimation data q having an absolute value proportional to the level difference Δ and a polarity corresponding to the bits of the reproducing LDPC code.

### THIRD EMBODIMENT

A code (hereinafter, referred to as a 5:9 code) in which two of nine pixels are “1” and the other seven pixels are “0” may be employed as the block code. An example of the encoding rule of the 5:9 code is partially illustrated in FIG. 11.

In this case, the block decoder 5 selects two of the nine pixels constituting a code word of the 5:9 code in order of increasing brightness, and it is assumed that the levels of the two selected pixels are p₁ and P₂ and that the levels of the other seven pixels are p₃, p₄, P₅, P₆, P₇, P₈, and p₉. The level difference Δ may be given by any one of equation 34, equation 35, or equation 36. Since 8 may be expressed as 2³, that is, a power of 2, the number 8 is set as a denominator of the second term in the right side of equation 35 and equation 36 for easy division in a digital circuit. When the reproducing signal p passes through a high-pass filter, the second term in the right side of equation 36 is almost 0 and is removed, and thus the level difference Δ may be given by equation 37.

$$\begin{matrix}Δ = ( {p}_{1} + {p}_{2} ) - ( {p}_{3} + {p}_{4} + {p}_{5} + {p}_{6} + {p}_{7} + {p}_{8} + {p}_{9} ) & ( 34 ) \\ Δ = \frac{{p}_{1} + {p}_{2}}{2} - \frac{{p}_{3} + {p}_{4} + {p}_{5} + {p}_{6} + {p}_{7} + {p}_{8} + {p}_{9}}{8} & ( 35 ) \\ Δ = \frac{{p}_{1} + {p}_{2}}{2} - \frac{{p}_{1} + {p}_{2} + {p}_{3} + {p}_{4} + {p}_{5} + {p}_{6} + {p}_{7} + {p}_{8} + {p}_{9}}{8} & ( 36 ) \\ Δ = \frac{{p}_{1} + {p}_{2}}{2} & ( 37 )\end{matrix}$$

In the case of a 5:9 code, the number of sets of pixels set to “1” is ₉C₂=36, but the number of sets of pixels used for a code word of a block code is 2⁵=32. Accordingly, there are 36-32=4 sets not existing in the code word. For example, the four sets shown in FIG. 12 may not be used in a code word.

However, as a result of allowing the block decoder 6 to select two of the nine pixels constituting a code word of a 5:9 code in order of increasing brightness, the sets shown in FIG. 6 exist. In this case, reliable estimation data cannot be obtained, and thus the block decoder 6 sets q=0 to the LDPC decoder 20. In the case of the 5:9 code, since the nine pixels correspond to the five bits of reproducing LDPC code, equation 38 is obtained. At this time, the LDPC decoder may perform the LDPC decoding process using the estimation data of another code word.
[q₁q₂q₃q₄q₅]=[00000] (38)

In the hologram recording and reproducing apparatus, a positional error between pixels of the space modulator and pixels of the light receiver may occur due to mechanical positional deviations of an optical system or contraction of the hologram recording medium. In order to prevent deterioration of performance due to the positional error, a technique called over-sampling may be used. In this technique, the pixels of the space modulator and the pixels of the light receiver do not correspond to each other by a ratio of 1:1, but, for example, a ratio of 1:4. Referring to FIG. 13, the recording-page data are mapped to the reproducing-page data twice, and four pixels of the block decoder 6 indicate 1 bit of the recording block code d. The block decoder 6 may use a numeral value obtained by adding the levels of the reproducing signal of the four pixels to obtain the reproducing signal of one pixel.

For simplification, in the above embodiments, a case where the parity check code is given by equation 6 and a code length N is 6 has been described. However, the code length N of the LDPC code may have several tens to several thousands of bits. In addition, for simplification, it has been described that operation 2 is repeated twice. However, the sum-product decoding method may be repeated four to several tens of times. The present invention may be applied to this case in a similar way as to the above examples.

Although embodiments in which the differential code, the 2:4 code, and the 5:9 code are employed as the block code have been described, the present invention is not limited to these embodiments. In addition, although it has been described that the estimation data q are proportional to the level difference Δ, the estimation data q may be any function of the level difference Δ, the function depending upon the probability distribution of various disturbances in the hologram recording and reproducing apparatus. The error correction code is not limited to the Reed-Solomon code, and other codes may be used. When the correction ability of the LDPC code is sufficiently high, the Reed-Solomon code and other error correction codes need not be employed.

Since the hologram recording and reproducing apparatus and the hologram reproducing apparatus according to the present invention each combine the block code and the LDPC code, it is possible to reproduce the reproducing data equal to the recording data with high reliability. In the conventional hologram recording and reproducing apparatus and the conventional hologram reproducing apparatus, the signal-to-noise (S/N) ratio of the reproducing signal may often be deteriorated due to various disturbances. However, with regard to both the hologram recording and reproducing apparatus and the hologram reproducing apparatus according to the present invention, by employing the LDPC code having a strong error correction ability, it is possible to reduce the bit error rate of the reproducing Reed-Solomon code.

In addition, in the reproducing-page data to be reproduced from the hologram recording medium, the brightness level of each pixel is changed due to various disturbances, and has a value included in a continuous range. In the hologram recording and reproducing apparatus and the hologram reproducing apparatus according to the present invention, since, in both cases, the estimation data of the LDPC code is calculated by effectively utilizing the level data of the reproducing signal having a value included in a continuous range, the error correction ability of the LDPC code may be enhanced, so that it is possible to reduce the bit error rate of the reproducing Reed-Solomon code.

Although a few embodiments of the present invention have been shown and described, it would be appreciated by those skilled in the art that changes may be made in this embodiment without departing from the principles and spirit of the invention, the scope of which is defined in the claims and their equivalents.

1. A hologram recording and reproducing apparatus comprising:
a low-density parity check encoding unit to encode recording data using a low-density parity check code and to generate a recording low-density parity check code;
a block encoding unit to encode the recording low-density parity check code using a block code and to generate a recording block code;
a hologram recording unit to record the data by emitting an object beam with a brightness modulated by a space modulator according to the recording block code onto a hologram recording medium;
a hologram reproducing unit including a light-receiver to reproduce the data by photo-electrically transforming a reproducing beam obtained by emitting a reference beam onto the hologram recording medium into a reproducing signal;
a block decoding unit to decode a reproducing block code corresponding to the recording block code based on the level of the reproducing signal, to decode a reproducing low-density parity check code corresponding to the recording low-density parity check code based on the reproducing block code, and to calculate estimation data to estimate values of respective bits of the reproducing low-density parity check code based on the level of the reproducing signal; and
a low-density parity check decoding unit to decode the low-density parity check code based on the estimation data and to decode the recording data.

2. The hologram recording and reproducing apparatus according to claim 1, wherein the absolute value of the estimation data is proportional to a difference in levels of the reproducing signal obtained from respective pixels of the light receiver.

3. The hologram recording and reproducing apparatus according to claim 2, wherein the polarity of the estimation data corresponds to the polarity of each of the bits of the reproducing low-density parity check code.

4. The hologram recording and reproducing apparatus according to claim 1, wherein the block encoding unit generates the recoding block code such that M of N pixels in the space modulator indicate “1” and (N-M) of the N pixels indicate “0” (where N and M are natural numbers, N>M).

5. The hologram recording and reproducing apparatus according to claim 4, wherein the block decoding unit selects M of the N pixels of the light receiver in an order of an increasing level of the reproducing signal, and decodes the reproducing block code by setting the selected M pixels to “1” and the (N-M) pixels to “0”.

6. The hologram recording and reproducing apparatus according to claim 5, wherein the block decoding unit adds the levels of the reproducing signal of the pixels set to “1”, subtracts the levels of the reproducing signal of the pixels set to “0”, and calculates the estimation data as being proportional to the added and subtracted levels.

7. The hologram recording and reproducing apparatus according to claim 1, wherein, when the reproducing block code does not exist in a code word of a block code, the estimation data of the respective bits of the reproducing low-density parity check code decoded based on the reproducing block code are set to 0.

8. A hologram reproducing apparatus to reproduce data recorded in a hologram recording medium by a hologram recorder including a low-density parity check encoding unit to encode recording data using a low-density parity check code and to generate a recording low-density parity check code, a block encoding unit to encode the recording low-density parity check code using a block code and to generate a recording block code, and a hologram recording unit to record the data by emitting an object beam with a brightness modulated by a space modulator according to the recording block code onto the hologram recording medium, the apparatus comprising:
a hologram reproducing unit including a light-receiver to reproduce the data by photo-electrically transforming a reproducing beam obtained by emitting a reference beam onto the hologram recording medium into a reproducing signal;
a block decoding unit to decode a reproducing block code corresponding to the recording block code based on the level of the reproducing signal, to decode a reproducing low-density parity check code corresponding to the recording low-density parity check code based on the reproducing block code, and to calculate estimation data to estimate values of respective bits of the reproducing low-density parity check code based on the level of the reproducing signal; and
a low-density parity check decoding unit to decode the low-density parity check code based on the estimation data and to decode the recording data.

9. The hologram reproducing apparatus according to claim 8, wherein the absolute value of the estimation data is proportional to a difference in levels of the reproducing signal obtained from respective pixels of the light receiver.

10. The hologram reproducing apparatus according to claim 9, wherein the polarity of the estimation data corresponds to the polarity of each of the bits of the reproducing low-density parity check code.

11. The hologram reproducing apparatus according to claim 8, wherein the block encoding unit generates the recoding block code such that M of N pixels in the space modulator indicate “1” and (N-M) of the N pixels indicate “0” (where N and M are natural numbers, N>M).

12. The hologram reproducing apparatus according to claim 11, wherein the block decoding unit selects M of the N pixels of the light receiver in order of an increasing level of the reproducing signal, and decodes the reproducing block code by setting the selected M pixels to “1” and the (N-M) pixels to “0”.

13. The hologram reproducing apparatus according to claim 12, wherein the block decoding unit adds the levels of the reproducing signal of the pixels set to “1”, subtracts the levels of the reproducing signal of the pixels set to “0”, and calculates the estimation data as being proportional to the added and subtracted levels.

14. The hologram reproducing apparatus according to claim 8, wherein, when the reproducing block code does not exist in a code word of a block code, the estimation data of the respective bits of the reproducing low-density parity check code decoded based on the reproducing block code are set to 0.

15. A hologram recording and reproducing apparatus comprising:
a low-density parity check (LDPC) encoder to encode recording data using a parity check code and to generate a recording LDPC code;
a block encoder to encode the recording LDPC code using a block code and to generate a recording block code;
a hologram recording unit to record the data by emitting an object beam onto a hologram recording medium;
a space modulator to modulate a brightness of the object beam according to the recording block code;
a hologram reproducing unit to reproduce the data by transforming a reproducing beam obtained by emitting a reference beam onto the hologram recording medium into a reproducing signal;
a block decoder to decode a reproducing block code corresponding to the recording block code based on level differences of the reproducing signal, to decode a reproducing LDPC code corresponding to the recording parity check code based on the reproducing block code, and to calculate estimation data to estimate values of respective bits of the reproducing LDPC code based on the level differences of the reproducing signal; and
an LDPC decoder to decode the LDPC code based on the estimation data and to decode the recording data.

16. The apparatus according to claim 15, wherein the hologram reproducing unit comprises a light receiver.

17. The apparatus according to claim 16, wherein, when a positional error between pixels of the space modulator and pixels of the light receiver occur, over-sampling of the reproduced data may be employed to increase accuracy of the reproduction.

18. The apparatus according to claim 15, wherein the estimation data may be any function of the level difference of the reproducing signal, as long as the function is dependent upon a probability distribution of various disturbances in the apparatus.

19. The apparatus according to claim 15, wherein the block code comprises a differential code.

20. The apparatus according to claim 15, wherein the block code comprises a 2:4 code and the block decoder compares the brightness levels of four pixels acting as code words of the 2:4 code and sets levels of the pixels to four levels in an order of increasing brightness.

21. The apparatus according to claim 15, wherein the block code comprises a 5:9 code and the block decoder selects two of nine pixels acting as a code word of the 5:9 code in an order of increasing brightness.

22. The apparatus according to claim 16, wherein an absolute value of the estimation data is proportional to a difference in levels of the reproducing signal obtained from respective pixels of the light receiver.

23. The apparatus according to claim 22, wherein the polarity of the estimation data corresponds to the polarity of each of the bits of the reproducing low-density parity check code.

24. The apparatus according to claim 16, wherein the block encoder generates the recording block code such that M of N pixels in the space modulator indicate “1” and (N-M) of the N pixels indicate “0” (where N and M are natural numbers, N>M).

25. The apparatus according to claim 24, wherein the block decoder selects M of the N pixels of the light receiver in an order of an increasing level of the reproducing signal, and decodes the reproducing block code by setting the selected M pixels to “1” and the (N-M) pixels to “0”.

26. The apparatus according to claim 25, wherein the block decoder adds the levels of the reproducing signal of the pixels set to “1”, subtracts the levels of the reproducing signal of the pixels set to “0 , and calculates the estimation data as being proportional to the added and subtracted levels.

27. The apparatus according to claim 15, wherein, when the reproducing block code does not exist in a code word of a block code, the estimation data of the respective bits of the reproducing low-density parity check code decoded based on the reproducing block code are set to 0.

28. The apparatus according to claim 15, wherein the block decoder calculates the level difference between the levels of the reproducing signal to obtain the estimation data.

29. The apparatus according to claim 15, wherein the LDPC encoder generates the recording LDPC code by multiplying input data by a generating matrix.

30. The apparatus according to claim 15, wherein the LDPC decoder decodes the LDPC code using a sum product decoding method.

31. The apparatus according to claim 30, wherein the sum product decoding method is preceded by the reception of the estimation data by the LDPC decoder.

32. The apparatus according to claim 15, wherein the LDPC decoder comprises a circuit structure having a pipeline shape into which continuous signals may be input.

33. The apparatus according to claim 15, wherein the LDPC decoder comprises a circuit structure having a circular shape into which continuous signals may be input and in which calculation results are fed back so as to update contents of a memory.

34. A method of processing and reproducing holographic data comprising:
encoding recording data and generating a recording Reed-Solomon code;
encoding the recording Reed-Solomon code and generating a recording low-density parity check (LDPC) code;
encoding the recording LDPC code and generating a recording block code;
transmitting and/or intercepting towards and/or from a hologram recording medium object beams of respective pixels and generating recording-page data having a checkered pattern corresponding to the recording block code;
converting the recording-page data into a reproducing signal;
decoding a reproducing block code corresponding to the recording block code based on the levels of the reproducing signal, decoding a reproducing LDPC code corresponding to the recording LDPC code based on the reproducing block code, and calculating estimation data to indicate the accuracy of respective bits of the reproducing LDPC code based on the levels of the reproducing signal p; and
decoding the LDPC code based on the estimation data and generating a reproducing Reed-Solomon code; and
decoding the reproducing Reed-Solomon code and generating reproducing data.

35. The method according to claim 34, wherein the encoding of the recording data comprises using a Reed-Solomon code, the encoding of the recording Reed-Solomon code comprises using an LDPC code, the encoding of the recording LDPC code comprises using a block code, and the decoding of the reproducing Reed-Solomon code comprises using a Reed-Solomon code.

36. An encoding and decoding apparatus including a hologram reproducing unit to generate a reproducing signal, the apparatus comprising:
a low-density parity check (LDPC) encoder to encode recording data and to generate a recording code;
a block encoder to encode the recording code using a block code and to generate a recording block code;
a block decoder to decode a reproducing block code corresponding to the recording block code based on level differences of the reproducing signal, to decode a reproducing code corresponding to the recording code based on the reproducing block code, and to calculate estimation data to estimate values of respective bits of the reproducing code based on the level differences of the reproducing signal; and
an LDPC decoder to decode the recording code based on the estimation data and to decode the recording data.
